(19) United States
(12) Patent Application Publication
(10) Pub. No.: US 2013/0025648 A1
(43) Pub. Date: Jan. 31, 2013

(54) SOLAR CELL ASSEMBLY

(71) Applicant: Tai-An HUNG, Tainan City (TW)

(72) Inventor: Tai-An HUNG, Tainan City (TW)

(73) Assignee: God Saw Co., Ltd., Tainan City (TW)

(21) Appl. No.: 13/560,581

(22) Filed: Jul. 27, 2012

(30) Foreign Application Priority Data
Jul. 29, 2011 (TW) 100127030

(51) Int. Cl. H01L 31/05

(52) U.S. Cl. 136/244

(57) ABSTRACT

A solar cell assembly includes a plurality of solar cells that are electrically connected to one another to forma series connection and that are aligned along an alignment direction. Each of the solar cells has opposite first and second end portions that are opposite to each other in the alignment direction. The first end portion of a subsequent one of the solar cells in the series connection is stacked on and is electrically connected to the second end portion of a preceding one of the solar cells in the series connection.

### CROSS-REFERENCE TO RELATED APPLICATION

This application claims priority of Taiwanese application no. 100127030, filed on Jul. 29, 2011,

### BACKGROUND OF THE INVENTION

1. Field of the Invention

The invention relates to a solar cell assembly, and more particularly to a solar cell assembly including a plurality of solar cells that are partially stacked one above the other.

2. Description of the Related Art

Referring to FIG. 1, U.S. Patent Application Publication No. 2011/0265849 discloses a solar cell panel that includes a plurality of solar cells 10, interconnectors 11 for electrically connecting in series the solar cells 10 to one another, and front and back protective layers (not shown) sandwiching the solar cells 10 and the interconnectors 11. The solar cell panel thus formed is disadvantageous in that an undesired gap 13 is formed between two adjacent ones of the solar cells 10, which results in a waste of space for the solar cell panel. In addition, the use of the interconnectors 11 in the solar cell panel increases the manufacturing costs.

### SUMMARY OF THE INVENTION

Therefore, the object of the present invention is to provide a solar cell assembly that can overcome the aforesaid drawbacks associated with the prior art.

According to the present invention, there is provided a solar cell assembly that comprises a plurality of solar cells that are electrically connected to one another to form a series connection and that are aligned along an alignment direction. Each of the solar cells has opposite first and second end portions that are opposite to each other in the alignment direction. The first end portion of a subsequent one of the solar cells in the series connection is stacked on and is electrically connected to the second end portion of a preceding one of the solar cells in the series connection.

### BRIEF DESCRIPTION OF THE DRAWINGS

In drawings which illustrate embodiments of the invention,

FIG. 1 is a schematic view of a conventional solar cell panel;

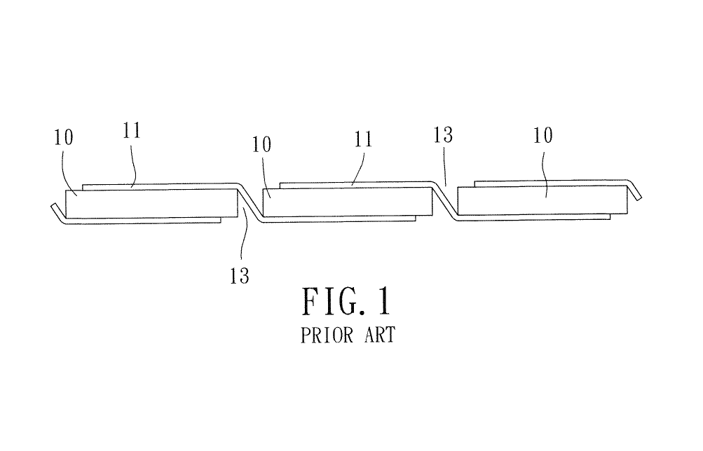

FIG. 2 is a perspective view of the first preferred embodiment of a solar cell assembly according to the present invention;

FIG. 3 is a perspective view of a solar cell modified from a solar cell of the first preferred embodiment; and

FIG. 4 is a perspective view of the second preferred embodiment of a solar cell assembly according to the present invention.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

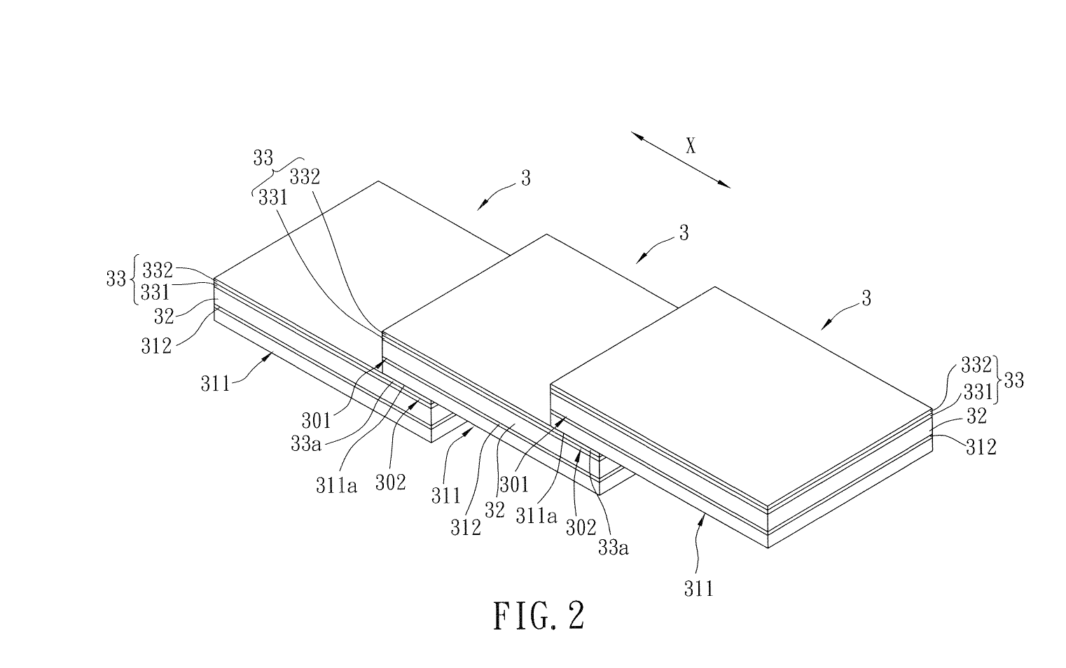

FIG. 2 illustrates the first preferred embodiment of a solar cell assembly according to the present invention. The solar cell assembly includes a plurality of solar cells 3 that are electrically connected to one another to form a series connection and that are aligned along an alignment direction (X). Each of the solar cells 3 has opposite first and second end portions 301, 302 that are opposite to each other in the alignment direction (X). The first end portion 301 of a subsequent one of the solar cells 3 in the series connection is stacked on and is electrically connected to the second end portion 302 of a preceding one of the solar cells 3 in the series connection.

In this embodiment, each of the solar cells 3 includes a metallic substrate 311, a back electrode layer 312 formed on the metallic substrate 311, a top electrode layer structure 33 disposed at one side of the back electrode layer 312 opposite to the metallic substrate 311, and a semiconductor photovoltaic layer 32 disposed between the back electrode layer 312 and the top electrode layer structure 33 and defining a p-n junction (not shown) for conversion of an incident light into an electrical current.

The metallic substrate 311 of each of the solar cells 3 has an end portion 311a corresponding to the first end portion 301 of the respective one of the solar cells 3. The top electrode layer structure 33 of each of the solar cells 3 has an end portion 33a corresponding to the second end portion 302 of the respective one of the solar cells 3. The end portion 311a of the metallic substrate 311 of each subsequent one of the solar cells 3 in the series connection is bonded to the end portion 33a of the top electrode layer structure 33 of the preceding one of the solar cells 3 in the series connection through a conductive paste (not shown).

Preferably, the metallic substrate 311 is flexible, and is made from a metallic material selected from Fe, Cr, Ni, and combinations thereof. In one example, the metallic substrate 311 is made from stainless steel having a composition comprising 60-77 wt % of Fe, 15-32 wt % of Cr, and 8-25 wt % of Ni.

Preferably, the back electrode layer 312 is made from a metal, such as molybdenum (Mo).

Preferably, the semiconductor photovoltaic layer 32 is made from a semiconductor material selected from Si, CdTe, CuInSe, and CuInGaSe.

The top electrode layer structure 33 includes a transparent current diffusion layer 331 formed on the semiconductor photovoltaic layer 32, and a transparent front electrode layer 332 formed on the current diffusion layer 331. Preferably, the transparent current diffusion layer 331 is made from a transparent conductive material selected from indium tin oxide and zinc oxide, and has a layer thickness less than 0.05 μm. Preferably, the transparent front electrode layer 332 is made from aluminum-doped zinc oxide (ZnO:Al), and has a layer thickness ranging from 0.5-1.5 μm.

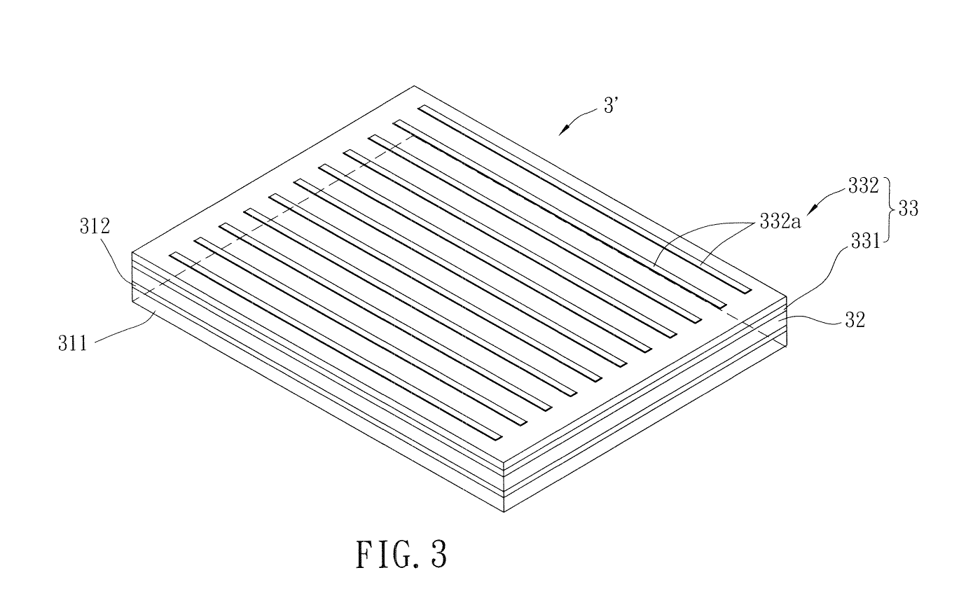

FIG. 3 illustrates a solar cell 3′ modified from the solar cell 3 of the first preferred embodiment. The solar cell 3′ differs from the solar cell 3 of the first preferred embodiment in that the transparent front electrode layer 332 has a plurality of conductive strips 332a that are spaced apart from one another and that are made from a metallic material. Each of the conductive strips 332a of each of the solar cells 3′ extends from the first end portion 301 to the second end portion 302 of the respective one of the solar cells 3′. Alternatively, if the conductive strips 332a have a width sufficiently narrow to not adversely affect transmission of incident light into the solar cell assembly, the conductive strips 332a may be nontransparent.

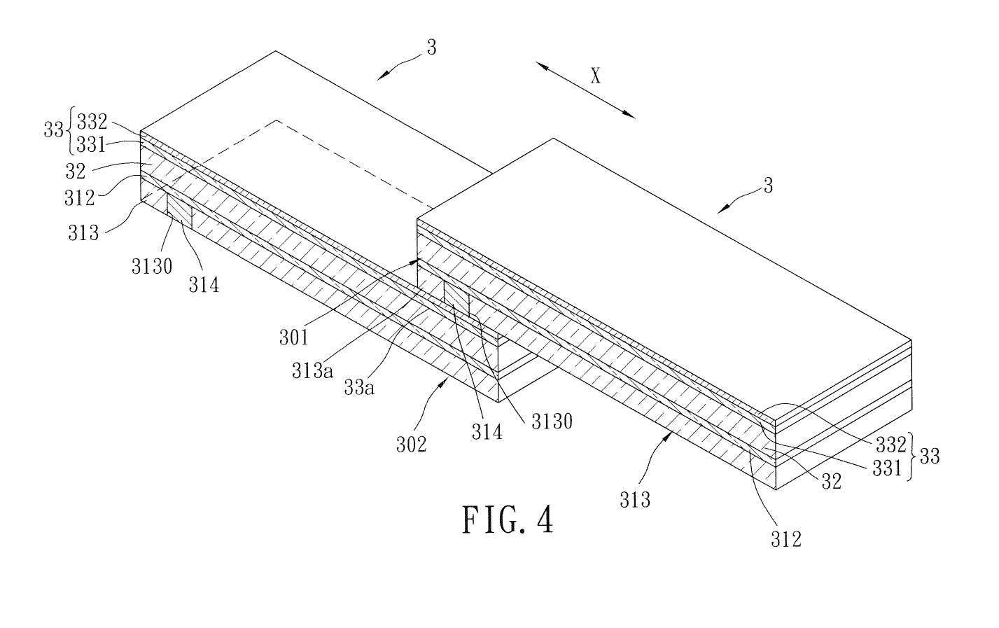

FIG. 4 illustrates the second preferred embodiment of the solar cell assembly according to the present invention. The second preferred embodiment differs from the previous preferred embodiment in that each of the solar cells 3 includes a non-conductive substrate 313 formed with a through-hole 3130, aback electrode layer 312 formed on the non-conductive substrate 313, a conductive connecting block 314 filling the through-hole 3130 and connected to the back electrode layer 312, a top electrode layer structure 33 disposed at one side of the back electrode layer 312 opposite to the non-conductive substrate 313, and a semiconductor photovoltaic layer 32 disposed between the back electrode layer 312 and the top electrode layer structure 33. The non-conductive substrate 313 of each of the solar cells 3 has an end portion 313a corresponding to the first end portion 301 of the respective one of the solar cells 3. The through-hole 3130 is formed in the end portion 313a of the non-conductive substrate 313. The top electrode layer structure 33 of each of the solar cells 3 has an end portion 33a corresponding to the second end portion 302 of the respective one of the solar cells 3. The end portion 313a of the non-conductive substrate 313 of each subsequent one of the solar cells 3 in the series connection together with the conductive connecting block 314 is bonded to the end portion 33a of the top electrode layer structure 33 of the preceding one of the solar cells 3 in the series connection.

Preferably, the non-conductive substrate 313 is made from glass or a polymeric material, such as polyimide or polyester.

Preferably, the conductive connecting block 314 is made from a metal selected from Au, Ag, Cu, and W.

By partially stacking the solar cells 3 one above the other to electrically connect in series the solar cells 3 of the solar cell assembly of this invention, the aforesaid drawbacks associated with the prior art can be eliminated.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A solar cell assembly comprising:
a plurality of solar cells that are electrically connected to one another to forma series connection and that are aligned along an alignment direction, each of said solar cells having opposite first and second end portions that are opposite to each other in said alignment direction, said first end portion of a subsequent one of said solar cells in the series connection being stacked on and being electrically connected to said second end portion of a preceding one of said solar cells in the series connection.

2. The solar cell assembly of claim 1, wherein each of said solar cells includes a metallic substrate, a back electrode layer formed on said metallic substrate, a top electrode layer structure disposed at one side of said back electrode layer opposite to said metallic substrate, and a semiconductor photovoltaic layer disposed between said back electrode layer and said top electrode layer structure, said metallic substrate of each of said solar cells having an end portion corresponding to said first end portion of the respective one of said solar cells, said top electrode layer structure of each of said solar cells having an end portion corresponding to said second end portion of the respective one of said solar cells, said end portion of said metallic substrate of each subsequent one of said solar cells in the series connection being bonded to said end portion of said top electrode layer structure of the preceding one of said solar cells in the series connection.

3. The solar cell assembly of claim 2, wherein said top electrode layer structure includes a transparent current diffusion layer formed on said semiconductor photovoltaic layer, and a transparent front electrode layer formed on said transparent current diffusion layer.

4. The solar cell assembly of claim 3, wherein said transparent current diffusion layer is made from a transparent conductive material selected from indium tin oxide and zinc oxide and has a layer thickness less than 0.05 μm.

5. The solar cell assembly of claim 3, wherein said transparent front electrode layer is made from aluminum-doped zinc oxide and has a layer thickness ranging from 0.5 μm to 1.5 μm.

6. The solar cell assembly of claim 2, wherein said top electrode layer structure includes a transparent current diffusion layer formed on said semiconductor photovoltaic layer, and a front electrode layer formed on said transparent current diffusion layer and having a plurality of conductive strips that are spaced apart from one another and that are made from a metallic material.

7. The solar cell assembly of claim 2, wherein said metallic substrate is flexible.

8. The solar cell assembly of claim 2, wherein said metallic substrate is made from a metallic material selected from Fe, Cr, Ni, and combinations thereof.

9. The solar cell assembly of claim 2, wherein said metallic substrate is made from stainless steel having a composition comprising 60-77 wt % of Fe, 15-32 wt % of Cr, and 8-25 wt % of Ni.

10. The solar cell assembly of claim 2, wherein said semiconductor photovoltaic layer is made from a semiconductor material selected from Si, CdTe, CuInSe, and CuInGaSe.

11. The solar cell assembly of claim 1, wherein each of said solar cells includes a non-conductive substrate formed with a through-hole, a back electrode layer formed on said non-conductive substrate, a conductive connecting block filling said through-hole and connected to said back electrode layer, a front electrode layer structure disposed at one side of said back electrode layer opposite to said non-conductive substrate, and a semiconductor photovoltaic layer disposed between said back electrode layer and said top electrode layer structure, said non-conductive substrate of each of said solar cells having an end portion corresponding to said first end portion of the respective one of said solar cells, said through-hole being formed in said end portion of said non-conductive substrate, said top electrode layer structure of each of said solar cells having an end portion corresponding to said second end portion of the respective one of said solar cells, said end portion of said non-conductive substrate of each subsequent one of said solar cells in the series connection together with said conductive connecting block being bonded to said end portion of said top electrode layer structure of the preceding one of said solar cells in the series connection.

12. The solar cell assembly of claim 11, wherein said non-conductive substrate is flexible.

13. The solar cell assembly of claim 11, wherein said non-conductive substrate is made from glass.

14. The solar cell assembly of claim 11, wherein said non-conductive substrate is made from a polymeric material selected from the group consisting of polyimide, polyester and combinations thereof.

15. The solar cell assembly of claim 11, wherein said semiconductor photovoltaic layer is made from a semiconductor material selected from Si, CdTe, CuInSe, and CuInGaSe.

16. The solar cell assembly of claim 11, wherein said conductive connecting block is made from a metal selected from the group consisting of Au, Ag, Cu, W and alloys thereof.

17. The solar cell assembly of claim 11, wherein said top electrode layer structure includes a transparent current diffusion layer formed on said semiconductor photovoltaic layer, and a transparent front electrode layer formed on said transparent current diffusion layer.

18. The solar cell assembly of claim 17, wherein said transparent current diffusion layer is made from a transparent conductive material selected from indium tin oxide and zinc oxide and has a layer thickness less than 0.05 μm.

19. The solar cell assembly of claim 17, wherein said transparent front electrode layer is made from aluminum-doped zinc oxide and has a layer thickness ranging from 0.5 μm to 1.5 μm.
